(19) United States
(12) Patent Application Publication
(10) Pub. No.: US 2025/0329519 A1
(43) Pub. Date: Oct. 23, 2025

(54) MOUNTING BASE, SUBSTRATE PROCESSING DEVICE, EDGE RING, AND EDGE RING TRANSFER METHOD

(71) Applicant: Tokyo Electron Limited, Tokyo (JP)

(72) Inventors: Yasuharu SASAKI, Miyagi (JP); Yohei UCHIDA, Miyagi (JP)

(73) Assignee: Tokyo Electron Limited, Tokyo (JP)

(21) Appl. No.: 19/258,907

(22) Filed: Jul. 3, 2025

Related U.S. Application Data
(63) Continuation of application No. 17/272,945, filed on Mar. 3, 2021.

(30) Foreign Application Priority Data
Sep. 6, 2018 (JP) 2018-167229

(51) Int. Cl. H01J 37/32

(52) U.S. Cl. CPC H01J 37/32807; H01J 37/32568; H01J 37/32642; H01J 37/32715; H01J 37/32091; H01J 2237/2007; H01J 2237/334

(57) ABSTRACT

A mounting base for placing a substrate to be subjected to a predetermined processing is provided. The mounting base includes an electrostatic chuck for electrostatically attracting and holding the substrate, a first edge ring that is disposed around the substrate and is transferrable, a second edge ring fixed around the first edge ring, a lifter pin for raising and lowering the first edge ring, a first electrode disposed in a position facing the first edge ring in the electrostatic chuck to electrostatically attract and hold the first edge ring; and a second electrode disposed in a position facing the second edge ring in the electrostatic chuck to electrostatically attract and hold the second edge ring.

### CROSS-REFERENCE TO RELATED APPLICATIONS

The present application is a continuation of U.S. patent application Ser. No. 17/272,945, filed on Mar. 3, 2021, which is based on PCT filing PCT/JP2019/033265, filed Aug. 26, 2019, which claims priority to JP 2018-167229, filed Sep. 6, 2018, the entire contents of each are incorporated herein by reference.

### TECHNICAL FIELD

The present disclosure relates to a mounting base, a substrate processing device, an edge ring, and an edge ring transfer method.

### BACKGROUND

For example, a mounting base of Patent Document 1 includes an electrostatic chuck and an edge ring.

### RELATED ART

Patent Document 1: Japanese Patent Application Publication No. 2008-244274

### SUMMARY

The present disclosure provides a technique for transferring an edge ring.

In accordance with an aspect of the present disclosure, there is provided a mounting base on which a substrate to be subjected to a predetermined processing is placed, the mounting base including: an electrostatic chuck configured to electrostatically attract and hold the substrate; a first edge ring that is transferrable and placed to surround the substrate; a second edge ring fixed to surround the first edge ring; a lifter pin configured to raise or lower the first edge ring; first a electrode for electrostatic attraction of the first edge ring, the first electrode being disposed at a position facing the first edge ring in the electrostatic chuck; and a second electrode for electrostatic attraction of the second edge ring, the second edge ring being disposed at a position facing the second edge ring in the electrostatic chuck.

### Effect

In accordance with the aspect of the present disclosure, it is possible to transfer the edge ring.

### BRIEF DESCRIPTION OF THE DRAWINGS

FIG. 1 is a vertical cross-sectional view showing a configuration of a substrate processing device according to an embodiment.

FIG. 2 is a vertical cross-sectional view showing a configuration around an edge ring according to the embodiment.

FIG. 3 is a diagram for explaining a relationship between the edge ring and a loading/unloading port according to the embodiment.

FIGS. 4A and 4B are diagrams showing an example of electrode patterns of the edge ring according to the embodiment.

FIG. 5 is a vertical cross-sectional view showing a configuration around an edge ring according to a modified example of the embodiment.

FIG. 6 is a flowchart showing an example of a replacement determination process according to the embodiment.

FIG. 7 is a flowchart showing an example of an edge ring replacement process according to the embodiment.

### DETAILED DESCRIPTION

Hereinafter, embodiments of the present disclosure will be described in detail with reference to the accompanying drawings. In this specification and the drawings, like reference numerals will be given to like parts having substantially the same functions, and redundant description thereof will be omitted.

### (Overall Configuration of Substrate Processing Device)

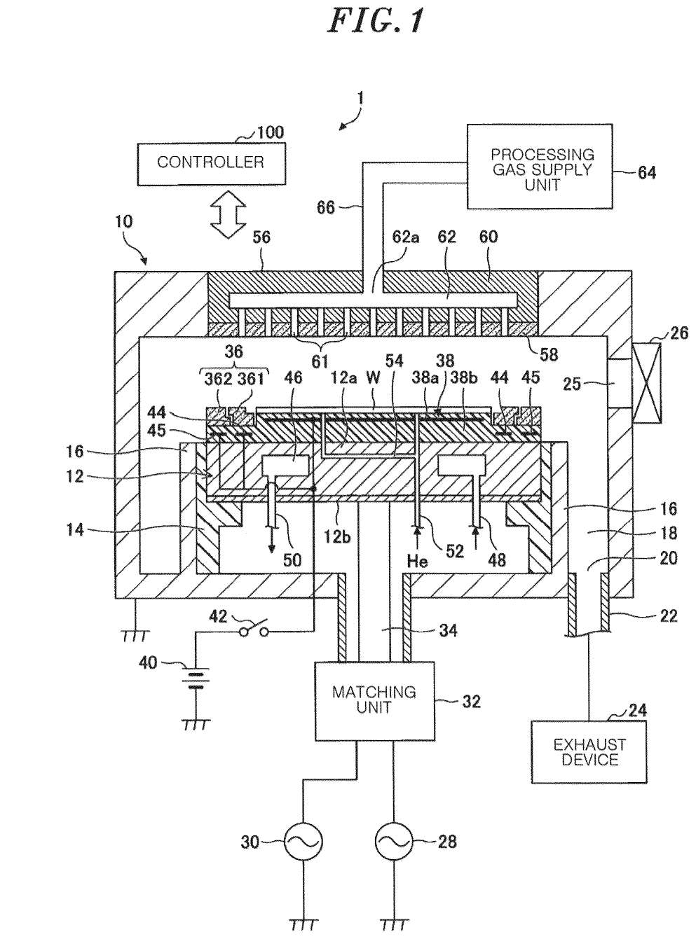

FIG. 1 shows an example of a configuration of a substrate processing device 1 according to an embodiment. The substrate processing device 1 is configured as a capacitively coupled plasma processing device and includes a cylindrical processing chamber 10 that is made of a metal such as aluminum or stainless steel. The processing chamber 10 is frame-grounded.

In the processing chamber 10, a disk-shaped mounting base 12, on which a wafer W that is an example of a substrate is placed, is horizontally disposed. The mounting base 12 serves as a lower electrode. The mounting base 12 includes a main body or a base 12a made of, for example, aluminum and a conductive RF plate 12b fixed to a bottom surface of the base 12a. The mounting base 12 is supported by a cylindrical insulating support 14 extending vertically upward from the bottom of the processing chamber 10. A cylindrical conductive support 16 extending vertically upward from the bottom of the processing chamber 10 is formed along an outer circumference of the cylindrical insulating support 14. An annular exhaust passage 18 is formed between the cylindrical conductive support 16 and an inner wall of the processing chamber 10, and an exhaust port 20 is formed at a bottom portion of the exhaust passage 18. An exhaust device 24 is connected to the exhaust port 20 through an exhaust pipe 22. The exhaust device 24 includes a vacuum pump such as a turbo molecular pump. The exhaust device 24 is configured to reduce a pressure of a processing space in the processing chamber 10 to a desired vacuum level. Further, a loading/unloading port 25 for loading and unloading the wafer W and a gate valve 26 for opening and closing the loading/unloading port 25 are provided at a sidewall of the processing chamber 10.

A first radio frequency (RF) power supply 30 and a second RF power supply 28 are electrically connected to the mounting base 12 via a matching unit 32 and a power feeding rod 34. The first RF power supply 30 is configured to output RF power having a predetermined frequency, for example, 40 MHZ, which mainly contributes to plasma generation. The second RF power supply 28 is configured to output RF power having a predetermined frequency, for example, 2 MHz, which mainly contributes to ion attraction to the wafer W on the mounting base 12. The matching unit 32 includes a first matching device and a second matching device. The first matching device is configured to match an impedance of the first RF power supply 30 side with an impedance of the load side (mainly the electrode, the plasma, and the processing chamber). The second matching device is configured to match an impedance of the second RF power supply 28 with an impedance of the load side (mainly the electrode, the plasma, and the processing chamber).

The mounting base 12 has a diameter larger than a diameter of the wafer W. An upper surface of the mounting base 12 is divided into two parts that are a wafer support portion in a central region having substantially the same shape (circular shape) and substantially the same size as the wafer W, and an annular peripheral portion extending in an outer peripheral region of the wafer support portion. The wafer W to be processed is placed on the wafer support portion. Further, an edge ring 36 having an inner diameter slightly larger than the diameter of the wafer W is placed on the annular peripheral portion to surround the wafer W. The edge ring 36 may be referred to as a focus ring. The edge ring 36 is made of a material such as silicon (Si), silicon carbide (SiC), carbon (C), silicon dioxide (SiO₂), or the like depending on an etching target material of the wafer W. The edge ring 36 includes a first edge ring that is an inner edge ring having an annular shape around the wafer W and a second edge ring that is an outer edge ring having an annular shape around the first edge ring.

The wafer support portion and the annular peripheral portion of the upper surface of the mounting base 12 respectively correspond to a mounting surface of a central portion and a mounting surface of an outer peripheral portion of an electrostatic chuck 38 that electrostatically attracts and holds the wafer. The electrostatic chuck 38 has a structure in which an electrode 38a having a sheet shape or a mesh shape is embedded in a dielectric member 38b having a film shape or a plate shape. The electrostatic chuck 38 is integrally formed or integrally fixed to the base 12a of the mounting base 12. A DC power supply 40 disposed outside the processing chamber 10 is electrically connected to the electrode 38a through a wiring and a switch 42. The electrostatic chuck 38 generates a Coulomb force by a DC voltage applied from the DC power supply 40, and the wafer W is electrostatically attracted and held on the electrostatic chuck 38 by the Coulomb force.

An upper surface of the outer peripheral portion of the electrostatic chuck 38 is brought into direct contact with a lower surface of the edge ring 36. A first electrode 44 and a second electrode 45, each of which is a conductor having a sheet shape or a mesh shape, are disposed at positions above the annular peripheral portion. The first electrode 44 is disposed in the electrostatic chuck 38 at a position facing (opposing) a first edge ring 361 so as to positionally correspond to the first edge ring 361, and the second electrode 45 is disposed in the electrostatic chuck 38 at a position facing (opposing) a second edge ring 362 so as to positionally correspond to the first edge ring 361.

The first electrode 44 and the second electrode 45 are electrically connected to the DC power supply 40. A DC voltage is supplied from the DC power supply 40 to the first electrode 44 and the second electrode 45. The supply and the shut-off of the supply of the DC voltage to the first electrode 44 and the second electrode 45 can be performed separately and independently for each electrode.

Therefore, the first edge ring 361 can be attracted and held on the annular peripheral portion of the electrostatic chuck 38 by a Coulomb force while the DC voltage is applied to the first electrode 44. Further, the second edge ring 362 can be attracted and held on the annular peripheral portion of the electrostatic chuck 38 by a Coulomb force while the DC voltage is applied to the second electrode 45.

In the mounting base 12, an annular coolant chamber 46 extending, for example, in a circumferential direction is formed. A coolant, for example, cooling water, having a predetermined temperature is supplied from a chiller unit (not shown) through pipes 48 and 50 and circulated in the coolant chamber 46. The temperatures of the wafer W and the edge ring on the electrostatic chuck 38 can be controlled by adjusting the temperature of the coolant.

A through-hole 54, through which a heat-exchange medium is supplied between the wafer W and the mounting surface of the center portion of the electrostatic chuck 38, is connected to a gas supply pipe 52. In such a configuration, a heat transfer gas, for example, He gas, from a heat transfer gas supply unit (not shown) passes through the gas supply pipe 52 and is supplied between the electrostatic chuck 38 and the wafer W through the through-hole 54 formed inside the mounting base 12. The heat transfer gas such as He gas is an example of the heat-exchange medium.

At a ceiling portion of the processing chamber 10, a shower head 56 having a ground potential is disposed in parallel so as to be opposite to the mounting base 12. The shower head 56 includes an electrode plate 58 disposed to be opposite to the mounting base 12 and an electrode holder 60 that detachably holds the electrode plate 58 from above. The shower head 56 also serves as an upper electrode. The electrode plate 58 is made of, for example, Si or Sic, and the electrode holder 60 is made of, for example, alumite-treated aluminum.

A gas chamber 62 is formed in the electrode holder 60, and a plurality of gas injection holes 61 extending downward from the gas chamber 62 toward the mounting base 12 are formed in the electrode support 60 and the electrode plate 58. With this configuration, a space between the electrode plate 58 and the mounting base 12 becomes a plasma generation space or a plasma processing space. A gas inlet port 62a is formed at an upper portion of the gas chamber 62, and a processing gas supply unit 64 is connected to the gas inlet port 62a through a gas supply pipe 66.

The operations of the respective components of the plasma processing device and the operation of the entire plasma processing device are controlled by, for example, a controller 100 including a computer. Examples of the respective components of the plasma processing device include the exhaust device 24, the first RF power supply 30, the second RF power supply 28, the switch 42 of the DC power supply 40, the chiller unit (not shown), the processing gas supply unit 64, and the like.

The controller 100 includes a read only memory (ROM) and a random access memory (RAM) that are not shown, and a microcomputer controls processing such as etching according to a procedure set in a recipe stored in the RAM or the like.

In order to perform a predetermined processing such as etching on the wafer W in the substrate processing device 1 having the above-described configuration, first, the gate valve 26 is opened and a processing target wafer W held on a transfer arm (not shown) is transferred into the processing chamber 10 through the loading/unloading port 25. The wafer W is held by pusher pins (not shown) above the wafer support portion of the electrostatic chuck 38, and the wafer W is placed on the wafer support portion of the electrostatic chuck 38 by lowering the pusher pins. The gate valve 26 is closed after the transfer arm is retracted. A pressure in the processing chamber 10 is reduced to a set value by the exhaust device 24.

Further, by applying a DC voltage(s) from the DC power supply 40 to the electrode 38a, the first electrode 44 and the second electrode 45 of the electrostatic chuck 38, the wafer W, the first edge ring 361 and the second edge ring 362 are electrostatically attracted and held onto the electrostatic chuck 38.

A processing gas supplied from the processing gas supply unit 64 is introduced into the processing chamber 10 in a shower-like manner through the shower head 56. Further, the RF power is output from each of the first RF power supply 30 and the second RF power supply 28 and is applied to the mounting base 12 through the power feeding rod 34. The introduced processing gas is turned into plasma by the RF power, and the wafer W is subjected to a predetermined processing such as etching with radicals and ions generated by the plasma. After the plasma processing is completed, the wafer W is held on the transfer arm and extracted to the outside of the processing chamber 10 through the loading/unloading port 25. By repeating the above-described process, the wafers W are consecutively processed.

### (Configurations of the Edge Ring and the Components Around the Edge Ring)

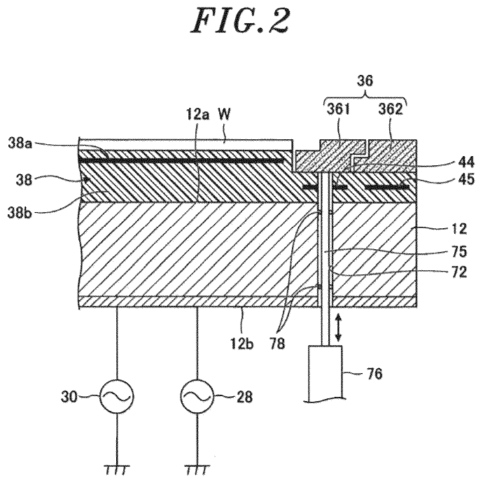

Hereinafter, configurations of the edge ring 36 and the components around the edge ring 36 will be described with reference to FIG. 2. FIG. 2 shows an enlarged view of the configuration of the electrostatic chuck 38 around the edge ring 36. The mounting surface of the outer peripheral portion of the electrostatic chuck 38 around the wafer W is located at a position lower than the mounting surface of the central portion of the electrostatic chuck 38. The annular edge ring 36, which is divided into a first edge ring 361 and a second edge ring 362, is disposed on the mounting surface of the outer peripheral portion of the electrostatic chuck 38. The first edge ring 361 is a transferrable inner edge ring disposed to surround the wafer W. The second edge ring 362 is a fixed outer edge ring fixed to surround the first edge ring 361. An upper surface of the wafer W placed on the mounting surface of the central portion of the electrostatic chuck 38, an upper surface of the first edge ring 361, and an upper surface of the second edge ring 362 are arranged so as to be substantially flush with one another.

The first edge ring 361 can be separated upward from the mounting base 12 by a lifter pin(s) 75 that raises and lowers the first edge ring 361, and a height position of the first edge ring 261 can be variably adjusted. A through-hole 72 vertically extending through the mounting base 12 is formed directly below the first edge ring 361. The lifter pin 75 is slidably moved in the through-hole 72. The through-hole 72 is an example of a first through-hole in which the lifter pin 75 is disposed.

A tip end of the lifter pin 75 comes into contact with a lower surface of the first edge ring 361. A base end of the lifter pin 75 is fixed to an actuator 76 disposed outside the processing chamber 10. The actuator 76 can arbitrarily adjust the height position of the first edge ring 361 by moving the lifter pin 75 vertically. A seal member(s) 78 such as an O-ring is provided in the through-hole 72. It is preferable to provide a plurality of through-holes 72, a plurality of lifter pins 75, and a plurality of actuators 76 at multiple locations (for example, three locations) at predetermined intervals in the circumferential direction.

When transferring the first edge ring 361, the lifter pin 75 is moved vertically by the actuator 76 to arbitrarily adjust the height position of the first edge ring 361. Then, the gate valve 26 is opened and the transfer arm is moved into the processing chamber 10 through the loading/unloading port 25. Then, the lifter pin 75 is lowered, and the first edge ring 361 is placed on the transfer arm.

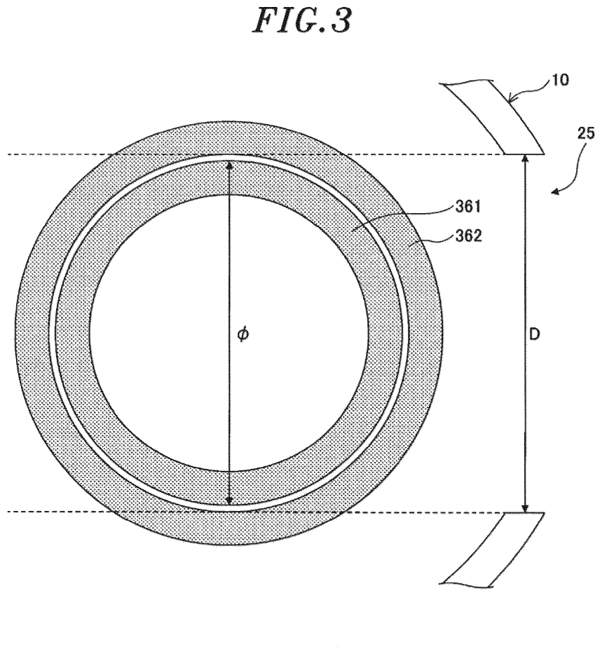

FIG. 3 is a schematic view of the first edge ring 361 and the second edge ring 362 in a plan view. An outer diameter φ of the first edge ring 361 is formed to be smaller than a width D of the loading/unloading port 25 for transferring the substrate that is formed at the processing chamber 10. Accordingly, the first edge ring 361 can be transferred from the inside to the outside or the outside to the inside of the processing chamber 10 through the loading/unloading port 25 while being held by the transfer arm. As shown in FIG. 2, the first edge ring 361 to be replaced is transferred from the lifter pin 75 to the transfer arm by moving the lifter pin 75 vertically using the actuator 76. Then, the first edge ring 361 is extracted to the outside of the processing chamber 10 through the loading/unloading port 25. Thereafter, a new first edge ring 361 is held by the transfer arm and transferred into the inside of the processing chamber 10 through the loading/unloading port 25. Then, the new first edge ring 361 is placed on the mounting surface of the outer peripheral portion of the electrostatic chuck 38, which is an inner side of the second edge ring 362.

Since a diameter of the wafer W is 300 mm, the width D of the loading/unloading port 25 is made to be slightly larger than 300 mm in order to load and unload the wafer W into and from the processing chamber 10 through the loading/unloading port 25. Meanwhile, in order to load and unload the edge ring 36 that is larger in size than the wafer W through the loading/unloading port 25, it is necessary for the edge ring 36 to have the outer diameter smaller than the width D of the loading/unloading port 25.

However, the outer diameter of the edge ring 36 is one of the process conditions for performing a predetermined processing on the wafer W. Thus, the outer diameter of the edge ring 36 needs to be equal to or larger than a predetermined value that is, for example, in a range from about 320 mm to 370 mm. Therefore, it is not possible to transfer the edge ring 36 with the loading/unloading port 25 unless the edge ring 36 is divided into parts.

In view of the above, the edge ring 36 according to the present embodiment is divided into a transferrable first edge ring 361 on the inner side and a fixed second edge ring 362 on the outer side. Further, the first edge ring 361 has a diameter φ smaller than the width D of the loading/unloading port 25, and can be transferred through the loading/unloading port 25. On the other hand, the second edge ring 362 has a diameter larger than the width D of the loading/unloading port 25, and is fixed to the electrostatic chuck 38 without being targeted for automatic transfer through the loading/unloading port 25. Therefore, the first edge ring 361 can be introduced and retracted through the loading/unloading port 25 in the same manner as the transfer of the wafer W without opening the lid of the processing chamber 10.

Further, in such a configuration, the DC voltage applied to the first electrode 44 and the DC voltage applied to the second electrode 45 can be controlled independently.

For example, the supply of the DC voltage to the first electrode 44 is stopped when the first edge ring 361 is transferred while the DC voltage is continuously supplied to the second electrode 45 facing the fixed second edge ring 362. Therefore, when the first edge ring 361 is transferred, the electrostatic attraction of the first edge ring 361 that is transferred is released while maintaining the electrostatic attraction of the second edge ring 362 that is not to be transferred.

### (Electrode Pattern)

As described above, the first electrode 44 and the second electrode 45 are independently controlled by the controller 100. Therefore, when the first edge ring 361 is transferred, the first edge ring 361 can be transferred while the position of the second edge ring 362 is fixed without displacement.

If each of the first electrode 44 and the second electrode 45 is a monopolar electrode, when a positive charge is supplied to the electrodes of the electrostatic chuck 38, it is necessary to collect a negative charge on the first edge ring 361 and the second edge ring 362 to thereby generate a Coulomb force. Therefore, the first edge ring 361 and the second edge ring 362 need a path leading to the ground. For while the plasma is being generated in the processing space, a path to the ground (grounded processing chamber 10) can be created through the plasma. Therefore, even if each of the first electrode 44 and the second electrode 45 is the monopolar electrode, the first edge ring 361 and the second edge ring 362 can be electrostatically attracted and held.

However, when the first edge ring 361 is transferred, plasma is not generated. Therefore, there is no path connecting the first edge ring 361 and the second edge ring 362 to the ground, so that the first edge ring 361 and the second edge ring 362 cannot be electrostatically attracted.

In view of the above, each of the first electrode 44 and the second electrode 45 according to the present embodiment is divided into a plurality of patterns (hereinafter, also referred to as “electrode patterns”). Further, separate voltages are applied to the plurality of electrode patterns divided from each of the first electrode 44 and the second electrode 45. In such a manner, each of the first electrode 44 and the second electrode 45 forms a bipolar electrode by generating a potential difference between the respective divided patterns, so that the first edge ring 361 and the second edge ring 362 can be electrostatically attracted and held independently.

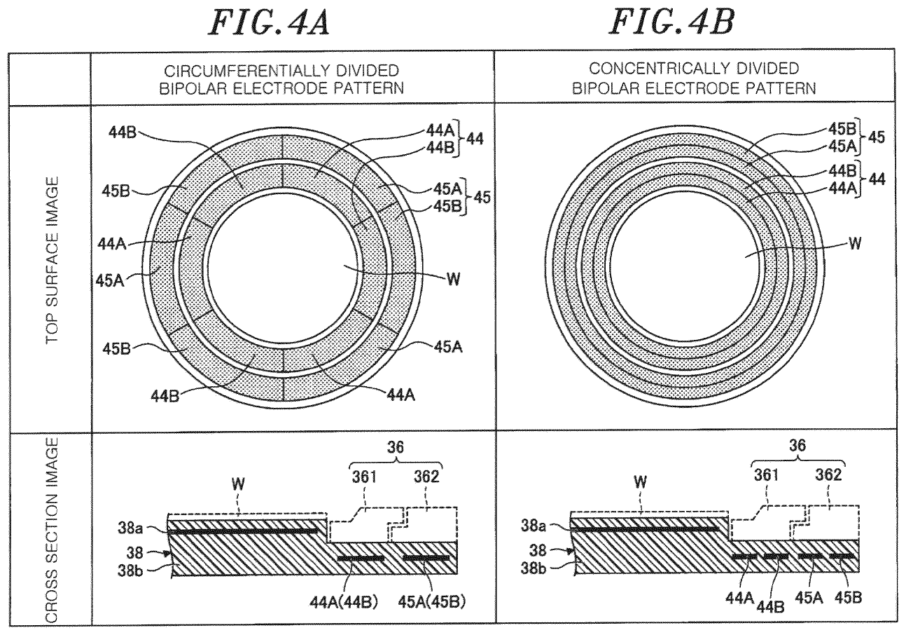

An upper diagram of each of FIGS. 4A and 4B shows an example of the electrode patterns of the upper (top) surfaces of the first electrode 44 and the second electrode 45. A lower diagram of each of FIGS. 4A and 4B shows an example of cross-sectional views of the first electrode 44 and the second electrode 45. FIG. 4A shows the electrode patterns of the bipolar electrode in which each of the first electrode 44 and the second electrode 45 is divided in the circumferential direction. FIG. 4B shows the electrode patterns of the bipolar electrode in which each of the first electrode 44 and the second electrode 45 is divided into concentric circles.

In the electrode patterns of FIG. 4A, the first electrode 44 is divided into six partial electrodes, which include three partial electrodes 44A and three partial electrodes 44B that are alternately arranged in the circumferential direction. Then, different DC voltages are applied to the partial electrode 44A and the partial electrode 44B, so that a potential difference is generated between the partial electrode 44A and the partial electrode 44B. Further, the second electrode 45 is divided into six partial electrodes, which include three partial electrodes 45A and three partial electrodes 45B that are alternately arranged, in the circumferential direction. Then, different DC voltages are applied to the partial electrode 45A and the partial electrode 45B, so that a potential difference is generated between the partial electrode 45A and the partial electrode 45B. In the electrode patterns of FIG. 4A, a case where each electrode is divided into six partial electrodes in the circumferential direction is described. However, the number of the divided partial electrodes is not limited thereto.

In the electrode patterns of FIG. 4B, the first electrode 44 is divided into two concentric partial electrodes including a partial electrode 44A and a partial electrode 44B. Then, different DC voltages are applied to the partial electrode 44A and the partial electrode 44B, so that a potential difference is generated between the partial electrode 44A and the partial electrode 44B. Further, the second electrode 45 is divided into two concentric partial electrodes including a partial electrode 45A and a partial electrode 45B. Then, different DC voltages are applied to the partial electrode 45A and the partial electrode 45B, so that a potential difference is generated between the partial electrode 45A and the partial electrode 45B. For any of the electrode patterns shown in FIGS. 4A and 4B, DC voltages having different polarities may be applied to the partial electrode 44A and the partial electrode 44B, or DC voltages having the same polarity but different magnitudes for generating the potential difference may be applied to the partial electrode 44A and the partial electrode 44B. Further, for the partial electrode 45A and the partial electrode 45B, DC voltages having different polarities may be applied thereto, or DC voltages having the same polarity but different magnitudes for generating the potential difference may be applied thereto.

Further, for any of the electrode patterns shown in FIGS. 4A and 4B, the areas of the partial electrode 44A and the partial electrode 44B are formed to be substantially the same, and the areas of the partial electrode 45A and the partial electrode 45B are formed to be substantially the same. Therefore, an electrostatic attraction force with the electrostatic chuck 38 can be generated in the electrode patterns of the bipolar electrode. Since polarization occurs in each of the first electrode 44 and the second electrode 45, the electrostatic attraction force can be generated independently between the electrostatic chuck 38 and the first edge ring 361 and between the electrostatic chuck 38 and the second edge ring 362.

In the present embodiment, an example of dividing the edge ring 36 into the first edge ring 361 and the second edge ring 362 has been described. However, the present disclosure is not limited thereto, and the edge ring 36 may be divided into three parts or four or more parts. In this case, one or more divided edge rings, each of which has a diameter smaller than the width D of the loading/unloading port 25, become the transfer targets, and one or more divided edge rings, each of which has a diameter larger than the width D of the loading/unloading port 25 are fixed onto the electrostatic chuck 38.

Meanwhile, when the edge ring that is fixed to the electrostatic chuck 38 (for example, the second edge ring 362 in the present embodiment) is consumed, the edge ring is manually replaced by opening the lid of the processing chamber 10.

However, since the transferrable edge ring (for example, the first edge ring 361 in the present embodiment) is disposed around the wafer W, a consumption amount due to the plasma processing is larger than that of the fixed edge ring. Further, even in the case of a similar degree of consumption, the transferrable edge ring disposed around the wafer W has a large influence on the process characteristics of an edge portion of the wafer W. Therefore, the number of times that the transferrable edge ring having a large influence on the process characteristics is replaced is greater than the number of times that the fixed edge ring having a small influence on the process characteristics is replaced. Therefore, in the present embodiment, the transferrable edge ring is automatically transferred through the loading/unloading port 25. Consequently, the process can be improved, and the time required for the replacement and maintenance of the edge ring can be shortened, thereby improving the productivity.

### (Modification Using Heat Transfer Gas Supply Unit)

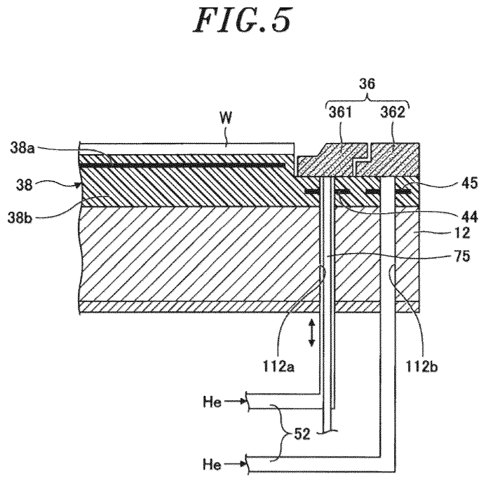

Next, a modified example using the heat transfer gas supply unit will be described with reference to FIG. 5. FIG. 5 is a vertical cross-sectional view showing the configuration around the edge ring 36 according to the modified example of the embodiment. In the modified example, a first through-hole 112a through which a heat-exchange medium is supplied to a gap between the first edge ring 361 and the mounting surface of the outer peripheral portion of the electrostatic chuck 38, and a second through-hole 112b through which a heat-exchange medium is supplied to a gap between the second edge ring 362 and the mounting surface of the outer peripheral portion of the electrostatic chuck 38. With such a configuration, the heat transfer gas, for example, He gas, from the heat transfer gas supply unit (not shown) passes through the gas supply pipe 52 and passes through the first through-hole 112a and the second through-hole 112b formed in the mounting base 12. Therefore, the heat transfer gas is supplied to a gap between the electrostatic chuck 38 and the wafer W and a gap between the electrostatic chuck 38 and the edge ring 36. The heat transfer gas such as He gas is merely an example of the heat-exchange medium.

In the modified example, the first through-hole 112a through which the heat transfer gas is supplied may be an example of the through-hole in which the lifter pin 75 is provided. With such a configuration, the heat transfer gas can be supplied to a gap between the first edge ring 361 and the electrostatic chuck 38 through the first through-hole 112a while the lifter pin 75 is raised and lowered.

Although it is not shown, the supply and shut-off of the supply of the heat transfer gas to the first through-hole 112a and the supply and shut-off of the supply of the heat transfer gas to the second through-hole 112b can be controlled separately. With such a configuration, a heat transfer rate of the heat transferred to the edge ring 36 can be controlled by supplying the heat transfer gas to a gap between the mounting surface of the outer peripheral portion of the electrostatic chuck 38 and a back surface of the edge ring 36 through the first through-hole 112a and the second through-hole 112b. Further, the first edge ring 361 can be transferred while improving the accuracy of temperature control of the edge ring 36.

### (Replacement Determination Process)

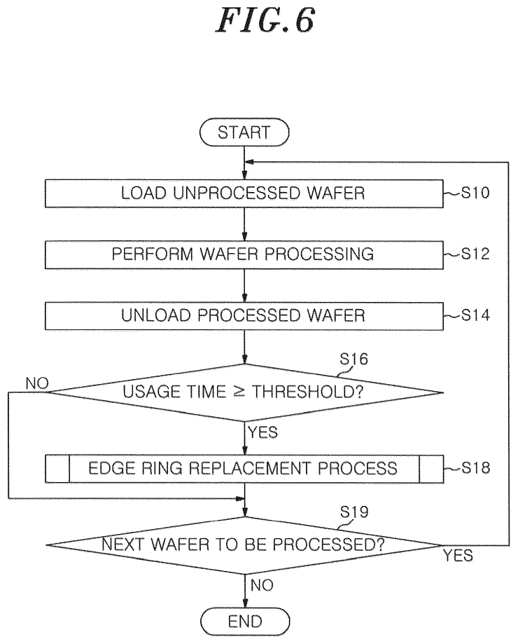

Next, in the example of the configuration of the edge ring 36 shown in FIG. 5, a replacement determination process for determining the replacement of the first edge ring 361 according to an embodiment will be described with reference to FIG. 6. FIG. 6 is a flowchart showing an example of the replacement determination process according to the embodiment. The replacement determination process is executed under the control of the controller 100.

When the replacement determination process is started, an unprocessed wafer is transferred into the processing chamber 10 and placed on the mounting base 12 in step S10. Next, in step S12, the wafer is subjected to a predetermined processing such as etching or film formation. Then, the wafer processed in step S14 is extracted from the processing container 10.

Next, in step S16, it is determined whether the usage time (wafer processing time) of the substrate processing device 1 is equal to or greater than a predetermined threshold. If the usage time is equal to or greater than the threshold, the first edge ring 361 is replaced in step S18, and then the process proceeds to step S19. If the usage time is less than the threshold, the process directly proceeds to step S19 without replacing the first edge ring 361.

Next, in step S19, it is determined whether or not there is a next wafer to be processed. If it is determined that the next wafer to be processed is present, the process returns to step S10 and the processes after step S10 are executed. If it is determined that no next wafer is present, the process is terminated.

Meanwhile, in step S16, the usage time of the substrate processing device 1 may be a RF power application time. Further, a consumption amount of the first edge ring 361 may be measured and used instead of the usage time, and the replacement of the first edge ring 361 may be determined based on the measurement result.

### (Edge Ring Replacement Process)

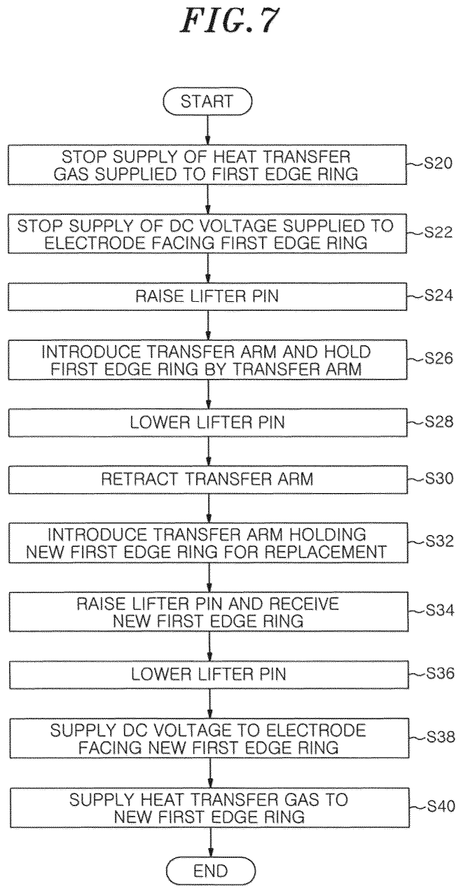

Next, an edge ring replacement process according to the embodiment that is executed in step S18 of FIG. 6 will be described with reference to FIG. 7. FIG. 7 is a flowchart showing an example of the edge ring replacement process according to the embodiment. The edge ring replacement process is executed under the control of the control unit 100. Further, in FIG. 7, the first edge ring 361 is a transferrable edge ring.

When the edge ring replacement process is executed, a supply of the heat transfer gas that is supplied toward the first edge ring 361 through the first through-hole 112a is stopped in step S20. Then, a supply of the DC voltage to the first electrode 44 disposed at the position facing the first edge ring 361 is stopped in step S22.

Next, in step S24, the lifter pin(s) 75 is raised, and the first edge ring 361 is lifted to a predetermined height position while being held on the lifter pin 75. Then, in step S26, the gate valve 26 is opened to allow the transfer arm to enter the processing chamber 10 through the loading/unloading port 25, and the first edge ring 361 held on the lifter pin 75 is transferred and held by the transfer arm.

Next, in step S28, the lifter pin 75 is lowered, and the transfer arm holding the first edge ring 361 is retracted through the loading/unloading port 25 in step S30. Thereafter, in step S32, the transfer arm holding a new first edge ring 361 for replacement enters the processing chamber 10 through the loading/unloading port 25. Then, in step S34, the lifter pin 75 is raised, and the lifter pin 75 receives the new first edge ring 361 for replacement from the transfer arm.

Next, in step S36, the lifter pin 75 is lowered. Then, in step S38, a DC voltage is supplied to the first electrode 44 facing the (new) first edge ring 361. Thereafter, in step S40, the heat transfer gas is supplied to the (new) first edge ring 361 through the first through-hole 112a. Therefore, the edge ring replacement process is completed, and the process returns to FIG. 6.

As described above, according to the transfer method of the present embodiment, the edge ring 36 can be divided into two parts, and the inner first edge ring 361 can be automatically transferred through the loading/unloading port 25. In addition, the optimum replacement timing can be determined, so that the first edge ring 361 can be automatically and rapidly transferred. As a result, the process can be improved, and the time required for the replacement and maintenance of the edge ring can be shortened, thereby improving the productivity.

Meanwhile, in the example of the configuration of the edge ring 36 shown in FIG. 2, when the replacement determination process of FIG. 6 is executed and the edge ring replacement process of FIG. 7 is called from step S18 of FIG. 6, steps S20 and S40 are skipped in the edge ring replacement process.

The mounting base, the substrate processing device, the edge ring and the method of transferring the edge ring according to the presently disclosed embodiments are considered in all respects to be illustrative and not restrictive. The above-described embodiments can be embodied in various forms. Further, the above-described embodiments may be omitted, replaced, or changed in various forms without departing from the scope of the appended claims and the gist thereof. The above-described embodiments may include other configurations without contradicting each other and may be combined without contradicting each other.

The substrate processing device of the present disclosure can be applied to any type of devices using capacitively coupled plasma (CCP), inductively coupled plasma (ICP), radial line slot antenna (RLSA), electron cyclotron resonance plasma (ECR), and helicon wave plasma (HWP).

In the present disclosure, the wafer W has been described as an example of the substrate. However, the substrate is not limited thereto, and may be various substrates used in a flat panel display (FPD, a printed circuit board, and the like.

This international application claims priority to Japanese Patent Application No. 2018-167229, filed on Sep. 6, 2018, and the entire contents of which are incorporated herein by reference.

### DESCRIPTION OF REFERENCE NUMERALS

1: substrate processing device
10: processing chamber
12: mounting base (lower electrode)
12a: mounting base main body (base)
12b: RF plate
24: exhaust device
28: second RF power supply
30: first RF power supply
32: matching unit
36: edge ring
361: first edge ring
362: second Edge ring
38: electrostatic chuck
38a: electrode
38b: dielectric member
40: DC power supply
44: first electrode
45: second electrode
56: shower head
75: lifter pin
76: actuator
100: controller
112a: first through-hole
112b: second through-hole

1. A mounting base on which a substrate to be subjected to a predetermined processing is placed, the mounting base comprising:
an electrostatic chuck configured to electrostatically attract and hold the substrate;
a first edge ring that is transferrable and placed to surround the substrate;
a second edge ring fixed to surround the first edge ring;
a lifter pin configured to raise or lower the first edge ring;
a first electrode for electrostatic attraction of the first edge ring, the first electrode being disposed at a position facing the first edge ring in the electrostatic chuck; and
a second electrode for electrostatic attraction of the second edge ring, the second edge ring being disposed at a position facing the second edge ring in the electrostatic chuck.

2. The mounting base of claim 1, wherein a diameter of the first edge ring is smaller than a width of a loading/unloading port through which the substrate is transferred, the loading/unloading port being formed at a processing chamber including the mounting base therein.

3. The mounting base of claim 1, further comprising:
a first through-hole through which a heat-exchange medium is supplied to a gap between the first edge ring and a mounting surface of the electrostatic chuck;
a second through-hole through which the heat-exchange medium is supplied to a gap between the second edge ring and the mounting surface of the electrostatic chuck.

4. The mounting base of claim 3, wherein the lifter pin is provided inside the first through-hole.

5. The mounting base of claim 1, wherein each of the first electrode and the second electrode is divided into a plurality of partial electrodes, and
separate voltages are applied to the partial electrodes of each of the first electrode and the second electrode.

6. A substrate processing device for performing predetermined processing on a substrate placed on a mounting base in a processing chamber, the substrate processing device comprising:
the mounting base on which the substrate is placed;
an electrostatic chuck configured to electrostatically attract and hold the substrate;
a first edge ring that is transferrable and placed to surround the substrate;
a second edge ring fixed to surround the first edge ring;
a lifter pin configured to raise or lower the first edge ring;
a first electrode for electrostatic attraction of the first edge ring, the first electrode being disposed at a position facing the first edge ring in the electrostatic chuck; and
a second electrode for electrostatic attraction of the second edge ring, the second edge ring being disposed at a position facing the second edge ring in the electrostatic chuck.

7. A method of transferring an edge ring including a first edge ring that is placed on a mounting base in a processing chamber of a substrate processing device and has a diameter smaller than a width of a loading/unloading port for the substrate that is formed at the processing chamber, and a second edge ring that is fixed on the mounting base and has a diameter larger than the width of the loading/unloading port, the method comprising:
transferring the first edge ring through the loading/unloading port.

8. The method of claim 7, wherein the transferring of the first edge ring includes:
stopping a supply of a DC voltage to a first electrode for electrostatic attraction of the first edge ring, the first electrode being disposed at a position facing the first edge ring;
raising a lifter pin configured to raise and lower the first edge ring;
allowing a transfer arm to enter the processing chamber and holding the first edge ring by the transfer arm; and
retracting the transfer arm from the processing chamber.

9. The method of claim 8, wherein the transferring of the first edge ring includes:
allowing the transfer arm holding the first edge ring for replacement to enter the processing chamber;
raising the lifter pin and receiving the first edge ring for replacement;
lowering the lifter pin and placing the first edge ring for replacement on the mounting base; and
supplying the DC voltage to the first electrode.

10. The method of claim 9, wherein, in the stopping of the supply of the DC voltage to the first electrode, the supply of the DC voltage to the first electrode is stopped after a supply of a heat-exchange medium to a gap between the first edge ring and a mounting surface of an electrostatic chuck through a through-hole is stopped.

11. The method of claim 10, wherein, in the supplying of the DC voltage to the first electrode, the DC voltage is supplied to the first electrode before the heat-exchange medium is supplied to the gap between the first edge ring and the mounting surface of the electrostatic chuck through the through-hole.

12. The method of claim 8, wherein the stopping of the supply of the DC voltage to the first electrode is performed while a DC voltage is supplied to a second electrode for electrostatic attraction of the second edge ring, the second electrode being disposed at a position facing the second edge ring.

13. The method of claim 7, further comprising:
determining replacement of the first edge ring,
wherein the transferring of the first edge ring is performed based on a result of the determination.
